(19) United States
(12) Patent Application Publication
(10) Pub. No.: US 2009/0148347 A1
(43) Pub. Date: Jun. 11, 2009

(54) NANO-CRYSTALLINE COMPOSITE-OXIDE THIN FILM, ENVIRONMENTAL GAS SENSOR USING THE THIN FILM, AND METHOD OF MANUFACTURING THE ENVIRONMENTAL GAS SENSOR

(75) Inventors: Su Jae LEE, Daejeon (KR); Jin Ah Park, Gyeongsangnam-do (KR); Jae Hyun Moon, Daejeon (KR); Tae Hyoung Zyung, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/190,991

(22) Filed: Aug. 13, 2008

(30) Foreign Application Priority Data
Dec. 10, 2007 (KR) 10-2007-0127778

(51) Int. Cl. G01N 7/00; C01B 13/14; H01L 21/36

(52) U.S. Cl. 422/83; 423/592.1; 438/487; 257/E21.134

(57) ABSTRACT

A nano-crystalline composite-oxide thin film for an environmental gas sensor, an environmental gas sensor using the thin film, and a method of manufacturing the environmental gas sensor are provided. The nano-crystalline composite-oxide thin film is formed of hetero-oxide nano-crystalline particles having independent crystalline phases from each other, and the environmental gas sensor including the thin film has excellent characteristics including high sensitivity, high selectivity, high stability and low power consumption.

### CROSS-REFERENCE TO RELATED APPLICATION

This application claims priority to and the benefit of Korean Patent Application No. 2007-127778, filed Dec. 10, 2007, the disclosure of which is incorporated herein by reference in its entirety.

### BACKGROUND

1. Field of the Invention

The present invention relates to a nano-crystalline composite-oxide thin film for a highly sensitive, selectable and stable environmental gas sensor, an environmental gas sensor using the thin film, and a method of manufacturing the environmental gas sensor. More particularly, the present invention relates to a nano-crystalline composite-oxide thin film formed of hetero-oxide nano-crystalline particles, a capacitive gas sensor for detecting an environmentally harmful gas using the thin film, and a method of manufacturing the gas sensor.

2. Discussion of Related Art

In recent times, new technologies such as a ubiquitous sensor system and an environment monitoring system have been developed.

Driven by the need to detect toxic and explosive gases, there is growing demand for a gas sensor capable of improving the quality of human life in areas such as health management, environment monitoring, industrial health and safety, home appliances and smart home systems, foods and agriculture, manufacturing, and national defense and anti-terror. Such a gas sensor would help to rid society of disaster, and thus there is need of more accurate measurement and control of environmentally harmful gases.

To commercialize such a gas sensor, some conditions must be met. First, the sensor has to have high detection sensitivity and enable detection of a gas at a low concentration. Second, the sensor has to selectively detect a specific gas and not be affected by other gases present. Third, the sensor has to be robust against the wears of time and unaffected by the surrounding environment such as the ambient temperature and humidity. Fourth, the sensor has to have a high response speed for rapid, repeated gas detection. Fifth, the sensor has to be multi-functional and consume a small amount of power. There have been steady efforts to develop gas sensors that meet these conditions using various materials and methods.

One type of gas sensors is gas sensors using ceramic, which includes semiconductor-type gas sensors, solid electrolyte-type gas sensors, and catalystic combustion-type gas sensors. Each of these types is further classified based on shape, structure and material. A considerable amount of research has focused on resistive environmental gas sensors, in which the electrical resistance of oxide semiconductor ceramic such as zinc oxide (ZnO), tin oxide (SnO₂), tungsten oxide (WO₃), titanium oxide (TiO₂) or indium oxide (In₂O₃) changes in response to gas absorption and oxidation-reduction reactions at the surface of the metal oxide when the oxide semiconductor ceramic is contacted with the environmental gases such as H₂, CO, O₂, CO₂, NOₓ, toxic gases, volatile organic gas, ammonia or water vapor. Some resistive environmental gas sensors are already used commercially.

Recent research is progressing toward the development of gas sensors using microscopic physical characteristics of nano structures, which are different from macroscopic characteristics of a bulk material. Such nano structures include an oxide nano thin film, nano particles, nano lines, nano fibers, nano tubes, nano pores and nano belts. Since these nano structures have a small size and a high surface-to-volume ratio, a sensor having a short response time and ultra-high sensitivity can be produced. These novel materials enable the development of a gas sensor having excellent characteristics including fast response speed, high sensitivity, high selectivity and low power consumption.

While the resistive gas sensor using an oxide semiconductor having a nano structure is highly sensitive, it is difficult to make it highly selective, stable in the long-term, and readily reproducible, due to instability of contact resistance and to unstable external environment.

Therefore, there is need for the development of new sensor materials and sensors that surpass the conventional gas sensor formed of an oxide semiconductor material and have excellent characteristics including high sensitivity, high selectivity, fast response speed and long-term stability.

Thus far, oxide materials such as ZnO, SnO₂, WO₃, TiO₂ and In₂O₃, used for metal oxide semiconductor ceramics, thin films and nano structures, have been known as good materials for developing a resistive environmental gas sensor, in which the electrical resistance of the oxide material changes in response to gas adsorption and oxidation-reduction reactions that occur on its surface due to contact with an environmental gas. Further, a considerable amount of research is focused on hetero-composite metal oxide ceramics such as composite-oxide ceramics including BaTiO₃-metal oxides (CaO, MgO, NiO, CuO, SnO₂, MgO, La₂O₃, Nd₂O₃, Y₂O₃, CeO₂, PbO, ZrO₂, Fe₂O₃, Bi₂O₃, V₂O₅, Nb₂O₅ and Al₂O₃, WO₃—(ZnO, CuO, NiO, SnO₂, MgO and Fe₂O₃), NiO—(V₂O₅, SrTiO₃, ZnO, In₂O₃, BaSnO₃), ZnO—(SnO₂, In₂O₃), and CoO—In₂O₃. Since the capacitance of these composite-oxide materials changes in response to gas adsorption and oxidation-reduction reactions that occur on their surface due to contact with an environmental gas, these are good materials for developing a capacitive gas sensor.

The capacitive gas sensor is intended to overcome the problems of the conventional resistive oxide semiconductor gas sensor and achieve low power consumption, high sensitivity, high selectivity and high gas reaction rate, since it is driven with an alternating voltage and can be formed smaller due to its simple structure. In particular, the capacitive gas sensor has long-term stability with regard to the external environment and can be highly integrated. In addition, the capacitance of the capacitive gas sensor can be easily raised by an oscillator circuit and the capacitive gas sensor is inexpensive because it has a simple signal processing circuit.

While research into composite-oxide ceramics for the development of a capacitive gas sensor has been conducted, no research into a nano-crystalline material for a composite-oxide thin film for a capacitive gas sensor has yet been reported.

### SUMMARY OF THE INVENTION

The present invention is directed to a commercial environmental gas sensor having the excellent characteristics described above, and more particularly, to a composite-oxide thin film for an environmental gas sensor which is formed of hetero-oxide nano-crystalline particles.

The present invention is also directed to a capacitive gas sensor having excellent gas reactivity characteristics, including high sensitivity, high selectivity, fast response speed and long-term stability, using a nano-crystalline composite-oxide thin film whose capacitance changes in response to gas adsorption and oxidation-reduction reactions occurring on its surface when contacted by an environmental gas.

The present invention is also directed to a method of manufacturing a capacitive gas sensor having excellent gas reactivity characteristics, including high sensitivity, high selectivity, fast response speed and long-term stability, using a nano-crystalline composite-oxide thin film whose capacitance changes in response to gas adsorption and oxidation-reduction reactions occurring on its surface when contacted by an environmental gas.

One aspect of the present invention provides a composite-oxide thin film for an environmental gas sensor, which is formed of hetero-oxide nano-crystalline particles having independent crystalline phases from each other.

For the composite-oxide thin film according to the present invention, at least two oxides may be selected from the group consisting of ABO₃-type perovskite oxides (BaTiO₃, metal-doped BaTiO₃, SrTiO₃ and BaSnO₃), ZnO, CuO, NiO, SnO₂, TiO₂, CoO, In₂O₃, WO₃, MgO, CaO, La₂O₃, Nd₂O₃, Y₂O₃, CeO₂, PbO, ZrO₂, Fe₂O₃, Bi₂O₃, V₂O₅, VO₂, Nb₂O₅, Co₃O₄ and Al₂O₃.

Further, the hetero-oxide nano-crystalline particles may have a diameter of 1 to 100 nm.

Another aspect of the present invention provides an environmental gas sensor, including: a substrate, a metal electrode formed on the substrate, and a composite-oxide thin film formed of hetero-oxide nano-crystalline particles on the metal electrode.

The substrate for an environmental gas sensor according to the present invention may be selected from the group consisting of oxide single crystalline and ceramic (MgO, LaAl₂O₃ and Al₂O₃) substrates, a silicon semiconductor (Si and SiO₂) substrate, and a glass substrate. The substrate may be formed to a thickness of 0.1 to 1 mm.

The metal electrode for an environmental gas sensor according to the present invention may include at least one selected from the group consisting of Pt, Au, Ag, Al, Ni, Ti, Cu and Cr.

The nano-crystalline composite-oxide thin film for an environmental gas sensor according to the present invention may be formed of hetero-oxide nano-crystalline particles having independent crystalline phases, and the oxide includes at least two selected from the group consisting of ABO₃-type perovskite oxides (BaTiO₃, metal-doped BaTiO₃, SrTiO₃ and BaSnO₃), ZnO, CuO, NiO, SnO₂, TiO₂, CoO, In₂O₃, WO₃, MgO, CaO, La₂O₃, Nd₂O₃, Y₂O₃, CeO₂, PbO, ZrO₂, Fe₂O₃, Bi₂O₃, V₂O₅, VO₂, Nb₂O₅, Co₃O₄ and Al₂O₃.

The nano-crystalline composite-oxide thin film may be formed to a thickness of 1 to 1000 nm.

Still another aspect of the present invention provides a method of manufacturing an environmental gas sensor, including: forming a metal electrode on a substrate, and growing hetero-oxide nano-crystalline particles on the substrate or the metal electrode to form a nano-crystalline composite-oxide thin film.

In the formation method according to the present invention, the growth of the hetero-oxide nano-crystalline particles may be performed by sputtering or pulsed laser deposition using a hetero-oxide ceramic target, or by pulsed laser deposition having a dual laser beam using two oxide ceramic targets.

In the formation method according to the present invention, the formation of the nano-crystalline composite-oxide thin film may be performed at a temperature ranging from room temperature to 800° C.

### BRIEF DESCRIPTION OF THE DRAWINGS

The above and other objects, features and advantages of the present invention will become more apparent to those of ordinary skill in the art by describing in detail preferred embodiments thereof with reference to the attached drawings, in which:

FIG. 1 is a perspective view of a capacitive environmental gas sensor having a nano-crystalline composite-oxide thin film according to an exemplary embodiment of the present invention;

FIG. 2 is a cross-sectional view of a hetero-oxide ceramic target used to form a nano-crystalline composite-oxide thin film according to an exemplary embodiment of the present invention;

FIG. 3 is a cross-sectional view illustrating a pulsed laser depositor used to form a nano-crystalline composite-oxide thin film according to an exemplary embodiment of the present invention;

FIG. 4 is a graph of θ-2θ X-ray diffraction patterns of a nano-crystalline CuO—Nb-doped BaTiO₃ composite-oxide thin film for an environmental gas sensor according to an exemplary embodiment of the present invention;

FIG. 5 is a scanning electron microscope (SEM) photograph of the surface of the nano-crystalline CuO—Nb-doped BaTiO₃ composite-oxide thin film for an environmental gas sensor according to the exemplary embodiment of the present invention;

FIG. 6 a graph showing results of energy dispersive X-ray spectroscopy (EDS) of the nano-crystalline CuO—Nb-doped BaTiO₃ composite-oxide thin film for an environmental gas sensor according to the exemplary embodiment of the present invention;

FIG. 7 is a graph of θ-2θ X-ray diffraction patterns of a nano-crystalline CuO—Nb-doped BaTiO₃ composite-oxide thin film for an environmental gas sensor according to another exemplary embodiment of the present invention;

FIG. 8 is a graph showing results of auger electron spectroscopy (AES) of the nano-crystalline CuO—Nb-doped BaTiO₃ composite-oxide thin film for an environmental gas sensor according to another exemplary embodiment of the present invention;

FIG. 9 is a graph of capacitance and dielectric loss versus frequency for a capacitive environmental gas sensor having the nano-crystalline CuO—Nb-doped BaTiO₃ composite-oxide thin film for an environmental gas sensor according to another exemplary embodiment of the present invention;

FIG. 10 is a graph of θ-2θ X-ray diffraction patterns of a nano-crystalline ZnO—NiO composite-oxide thin film for an environmental gas sensor according to still another exemplary embodiment of the present invention;

FIG. 11 is a graph of capacitance versus frequency for a capacitive environmental gas sensor having the nano-crystalline ZnO—NiO composite-oxide thin film for an environmental gas sensor according to still another exemplary embodiment of the present invention; and

FIG. 12 is a graph of dielectric loss versus frequency for the capacitive environmental gas sensor having the nano-crystalline ZnO—NiO composite-oxide thin film for an environmental gas sensor according to still another exemplary embodiment of the present invention.

### DETAILED DESCRIPTION OF EXEMPLARY EMBODIMENTS

A nano-crystalline composite-oxide thin film for an environmental gas sensor according to the present invention has a grain boundary formed by binding hetero-oxide nano-crystalline particles together, and has a capacitor with high resistance due to a potential barrier formed at the grain boundary. Accordingly, the capacitance of the thin film changes at the grain boundary in response to a reaction with an environmental gas.

A capacitive environmental gas sensor according to the present invention includes the nano-crystalline composite-oxide thin film having the above-mentioned characteristics on a substrate and/or a metal electrode, thereby having excellent characteristics such as high sensitivity, high selectivity, long-term stability and low power consumption, and further enabling its adoption as a next-generation ubiquitous sensor system and an environmental monitoring system, which are required for more accurate measurement and control of environmentally toxic gases.

Hereinafter, the present invention will be described in detail with reference to the accompanying drawings.

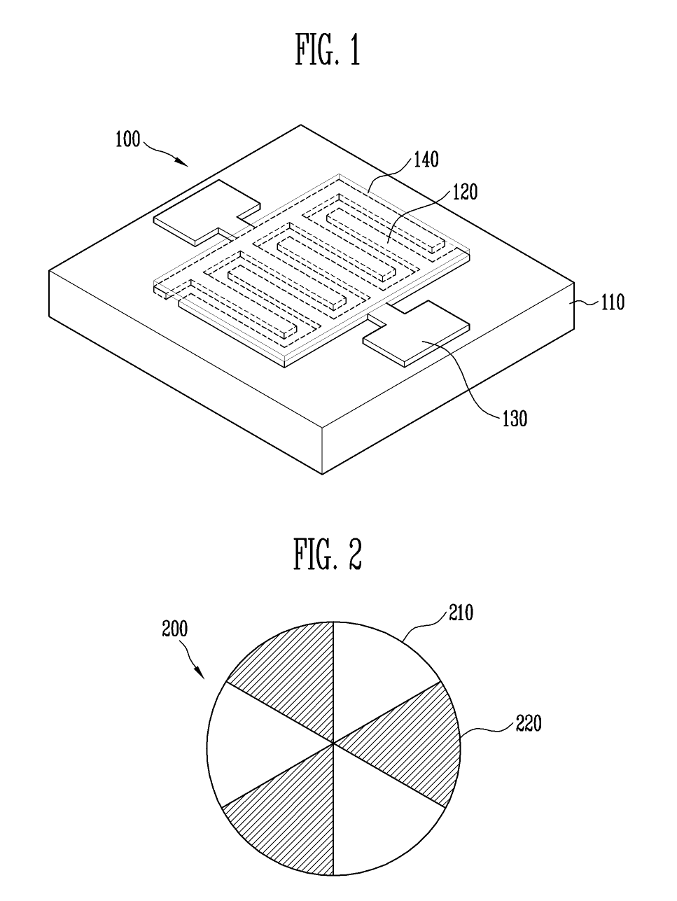

FIG. 1 is a perspective view of a capacitive environmental gas sensor according to an exemplary embodiment of the present invention.

Referring to FIG. 1, a capacitive environmental gas sensor 100 having a nano-crystalline composite-oxide thin film of the present invention includes a substrate 110, a metal electrode 120 and an electrode pad 130 formed on the substrate 110, and a nano-crystalline composite-oxide thin film 140 formed on the metal electrode 120.

The substrate 110 may be selected from oxide single crystalline and ceramic (MgO, LaAl₂O₃ or Al₂O₃) substrates, a silicon semiconductor (Si or SiO₂) substrate, and a glass substrate, and formed to a thickness of 0.1 to 1 mm.

The metal electrode 120 may be selected from the group consisting of platinum (Pt), gold (Au), silver (Ag), aluminum (Al), nickel (Ni), titanium (Ti), copper (Cu) and chromium (Cr), and formed to a thickness of 10 to 1000 nm.

The electrode pad 130, which is not necessarily included, may be formed of the same material as the metal electrode 120.

The nano-crystalline composite-oxide thin film 140 may include at least two oxides selected from the group consisting of ABO₃-type perovskite oxides (BaTiO₃, metal-doped BaTiO₃, SrTiO₃ and BaSnO₃), ZnO, CuO, NiO, SnO₂, TiO₂, CoO, In₂O₃, WO₃, MgO, CaO, La₂O₃, Nd₂O₃, Y₂O₃, CeO₂, PbO, ZrO₂, Fe₂O₃, Bi₂O₃, V₂O₅, VO₂, Nb₂O₅, Co₃O₄ and Al₂O₃.

Further, the nano-crystalline composite-oxide thin film 140 may be formed of hetero-oxide nano-crystalline particles having independent crystalline phases, and each crystalline particle may have a diameter of 1 to 100 nm. The smaller the nano-crystalline particles are, the more junctions are formed between the two hetero-oxide crystalline particles, the greater a specific area for sensing is, and higher the sensitivity of the sensor is.

In addition, the nano-crystalline composite-oxide thin film 140 may be formed to a thickness of 1 to 1000 nm.

The nano-crystalline composite-oxide thin film for an environmental gas sensor of the present invention may be formed by growing the nano-crystalline composite-oxide thin film 140 on the substrate 110 or the metal electrode 120 by single-beam pulsed laser deposition using a hetero-oxide ceramic target, pulsed laser deposition using a dual laser beam using two oxide ceramic targets, sputtering, or a sol-gel method.

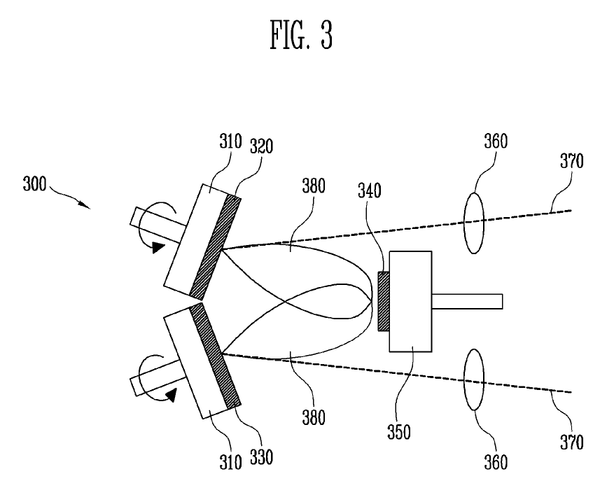

FIG. 2 is a cross-sectional view of a hetero-oxide ceramic target used to form a thin film by single-beam pulsed laser deposition.

The hetero-oxide ceramic target according to FIG. 2 includes a composite of an oxide ceramic target A 210 and an oxide ceramic target B 220, combined in any sequence such as AB, ABAB, ABABAB or ABABABAB.

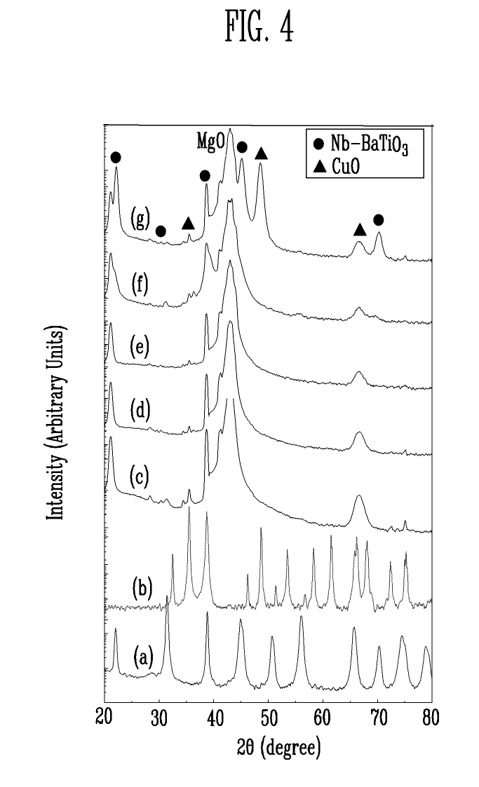

FIG. 3 illustrates a pulse laser depositor using a dual laser beam, which uses two oxide ceramic targets and two laser beams.

In FIG. 3, a pulse laser depositor 300 having a double laser beam includes a target holder 310, an oxide ceramic target A 320, an oxide ceramic target B 330, a substrate 340, a substrate holder and heater 350, a lens 360, a pulsed laser beam 370, and a flume 380.

Oxides for deposition are introduced to the oxide ceramic target A 320 and the oxide ceramic target B 330, respectively. Subsequently, the pulsed laser beam 370 is radiated at both oxide ceramic targets A and B 320 and 330, and oxide particles/molecules released from both oxide ceramic targets 320 and 330 are disposed on the substrate 340.

A composition ratio of a hetero-composite-oxide can be controlled depending on energy densities of the two laser beams 370.

### Exemplary Embodiments 1 to 5

Nano-Crystalline CuO—Nb-Doped BaTiO₃ Composite-Oxide Thin Film for Environmental Gas Sensor

A CuO oxide ceramic target and an Nb-doped BaTiO₃ oxide ceramic target were prepared. A hetero-composite-oxide target was divided into six segments, i.e., three of CuO oxide ceramic A, and three of Nb-doped BaTiO₃ oxide ceramic B, which resulted in an ABABAB structure. Subsequently, a nano-crystalline composite-oxide thin film was formed on a MgO (001) single crystalline substrate having a thickness of 0.5 mm by pulse laser ablation using the composite-oxide ceramic target including a composite of the CuO oxide ceramic and the Nb-doped BaTiO₃ oxide ceramic. A period of the pulse layer beam and rotational frequency of the composite-oxide target were synchronized such that CuO oxide and Nb-doped BaTiO₃ oxide were alternatively deposited on the substrate. Here, the hetero-composite-oxide thin film may be deposited at a temperature ranging from room temperature to 800° C., or deposited at room temperature and annealed at 300° C. or more. In the present embodiment, the nano-crystalline composite-oxide thin films were formed to a thickness of 144 nm by deposition at various temperatures, e.g., room temperature, 300, 400, 500 and 600° C., and annealing at 600° C.

Characteristics of the thin films of Exemplary embodiments 1 to were investigated.

FIG. 4 is a graph of θ-2θ X-ray diffraction patterns of the thin films of Exemplary embodiments 1 to 5.

Referring to FIG. 4, (a) is the x-ray diffraction pattern for an Nb-doped BaTiO₃ oxide ceramic target, (b) is the x-ray diffraction pattern for a CuO oxide ceramic target, (c) is the x-ray diffraction pattern for a CuO—Nb-doped BaTiO₃ composite-oxide thin film formed by deposition at room temperature and annealing at 600° C., and (d), (e), (f) and (g) are the x-ray diffraction patterns of CuO—Nb-doped BaTiO₃ composite-oxide thin films grown at deposition temperatures of 300, 400, 500 and 600° C., respectively. As seen from FIG. 4, in the nano-crystalline CuO—Nb-doped BaTiO₃ composite-oxide thin film, a crystalline phase of the CuO thin film is separated from a crystalline phase of the Nb-doped BaTiO₃ thin film. Thus, it can be noted that a hetero-nano-crystalline composite-oxide thin film is formed.

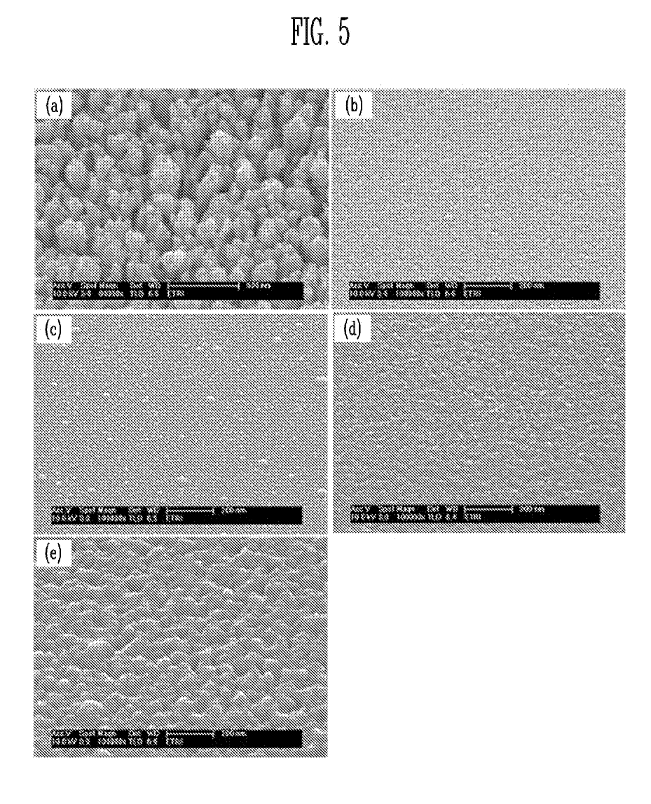

FIG. 5 illustrates scanning electron microscope (SEM) photographs of CuO—Nb-doped BaTiO₃ composite-oxide thin films formed in Exemplary embodiments 1 to 5. Referring to FIG. 5, (a) is the SEM photograph of the CuO—Nb-doped BaTiO₃ composite-oxide thin film formed by deposition at room temperature and annealing at 600° C., and (b) to (e) are the SEM photographs of the CuO—Nb-doped BaTiO₃ composite-oxide thin films grown at deposition temperatures of 300, 400, 500 and 600° C., respectively. It can be seen from FIG. 5 that the CuO—Nb-doped BaTiO₃ composite-oxide thin film is formed of nano-scale grains.

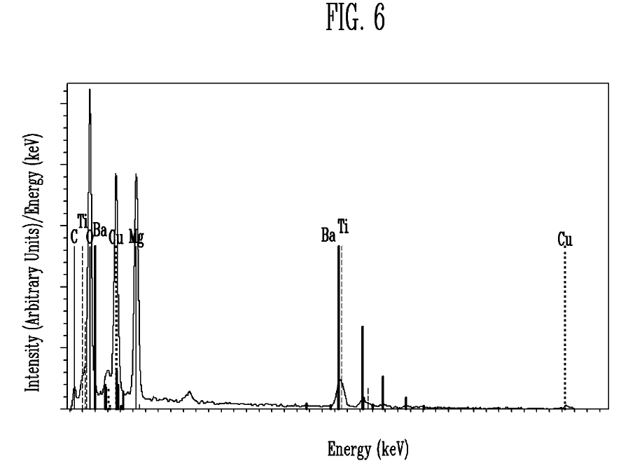

FIG. 6 illustrates the results of energy dispersive x-ray spectroscopy (EDS) of the CuO—Nb-doped BaTiO₃ composite-oxide thin film grown at a deposition temperature of 600° C. in Exemplary embodiment 5. Referring to FIG. 6, it can be seen that the CuO—Nb-doped BaTiO₃ composite-oxide thin film includes Cu, Ba, Ti and O.

### Exemplary Embodiments 6 to 11

Nano-Crystalline CuO—Nb-Doped BaTiO₃ Composite-Oxide Thin Film for Environmental Gas Sensor

A composite-oxide ceramic target having a composite of CuO and Nb-doped BaTiO₃ oxide ceramic was prepared by the method of Exemplary embodiment 1, and a nano-crystalline composite-oxide thin film was formed on a SiO₂/Si substrate having a thickness of 0.5 mm by pulse laser ablation. A period of the pulsed laser beam and rotation frequency of the composite-oxide target were synchronized, such that CuO oxide and Nb-doped BaTiO₃ oxide were alternatively deposited on the substrate. In the present embodiment, nano-crystalline composite-oxide thin films were formed to a thickness of 144 nm by deposition at various temperatures, e.g., room temperature, 300, 400, 500, 550 and 600° C., and annealing at 600° C.

Characteristics of the thin films of Exemplary embodiments 6 to 11 were investigated.

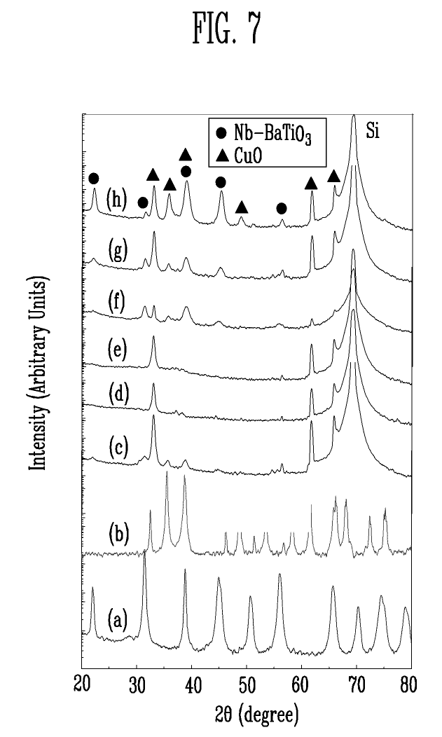

FIG. 7 is a graph of θ-2θ X-ray diffraction patterns of thin films of Exemplary embodiments 6 to 11. Referring to FIG. 7, (a) is the x-ray diffraction pattern for an Nb-doped BaTiO₃ oxide ceramic target, (b) is the x-ray diffraction pattern for a CuO oxide ceramic target, (c) is the x-ray diffraction pattern for a CuO—Nb-doped BaTiO₃ composite-oxide thin film formed by deposition at room temperature and annealing at 600° C., and (d), (e), (f), (g) and (h) are the x-ray diffraction patterns of CuO—Nb-doped BaTiO₃ composite-oxide thin films grown at deposition temperatures of 300, 400, 500, 550 and 600° C., respectively. According to FIG. 7, it can be seen that in the nano-crystalline CuO—Nb-doped BaTiO₃ composite-oxide thin film, a crystalline phase of the CuO thin film is separated from a crystalline phase of the Nb-doped BaTiO₃ thin film. Thus, it can be noted that a hetero-nano-crystalline composite-oxide thin film is formed.

FIG. 8 illustrates the results of Auger electron spectroscopy (AES) of the CuO—Nb-doped BaTiO₃ composite-oxide thin film of Exemplary embodiment 6. According to FIG. 8, it can be seen that the CuO—Nb-doped BaTiO₃ composite-oxide thin film includes Cu, Ba, Ti and O.

### Exemplary Embodiment 12

An interdigitated transducer electrode metal was formed to a thickness of 100 nm on a 0.5 mm SiO2/Si substrate, and the CuO—Nb-doped BaTiO₃ composite-oxide thin film formed in Exemplary embodiment 7 was formed on the electrode metal, such that a capacitive environmental gas sensor having the structure shown in FIG. 1 was manufactured.

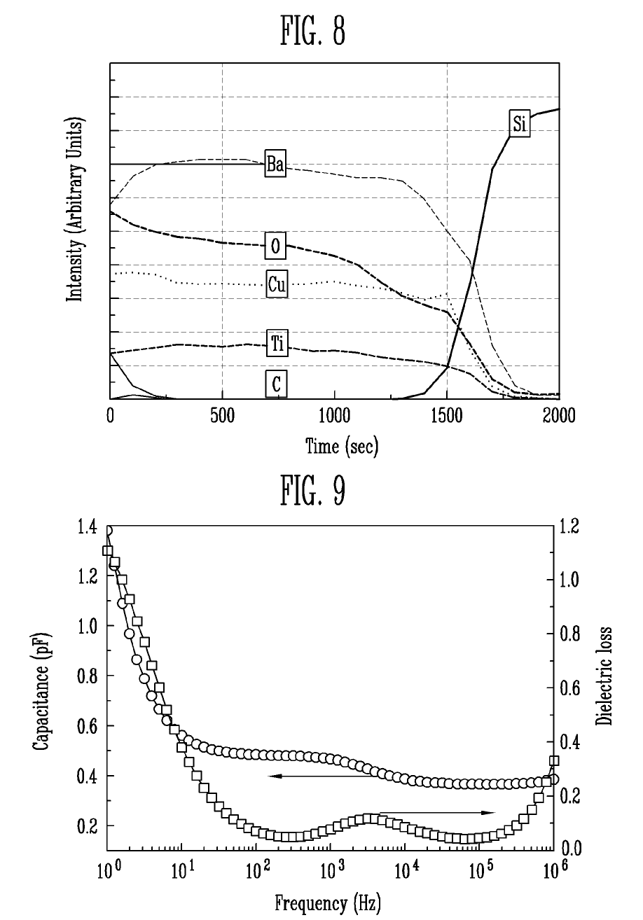

The capacitance and dielectric loss were estimated at different frequencies of the capacitive environmental gas sensor formed in Exemplary embodiment 12. FIG. 9 is a graph of capacitance and dielectric loss versus frequency of the capacitive environmental gas sensor formed in Exemplary embodiment 12. Referring to FIG. 9, the nano-crystalline CuO—Nb-doped BaTiO₃ composite-oxide thin film exhibits decreasing capacitance and a dielectric dispersion phenomenon, i.e., anomalous dielectric loss at a grain boundary between hetero nano-crystalline particles around a frequency of 2 kHz.

### Exemplary Embodiments 13 to 17

Nano-Crystalline ZnO—NiO Composite-Oxide Thin Film for Environmental Gas Sensor

A ZnO oxide ceramic target and a NiO oxide ceramic target were prepared. A ZnO—NiO composite-oxide target was divided into 6 segments, including three of ZnO oxide ceramic A and three of NiO oxide ceramic B, which resulted in an ABABAB structure. Subsequently, a nano-crystalline composite-oxide thin film was formed on a SiO₂/Si substrate having a thickness of 0.5 mm by pulse laser ablation using the composite-oxide target having a composite of ZnO and NiO oxide ceramics. A period of the pulsed laser beam and rotation frequency of the composite-oxide target were synchronized, such that ZnO oxide and NiO oxide were alternatively deposited on the substrate. In the present embodiment, the ZnO—NiO composite-oxide thin film was formed by deposition at room temperature and annealing at 400, 450, 500, 550 or 600° C., such that a nano-crystalline ZnO—NiO composite-oxide thin film was formed to a thickness of 120 nm.

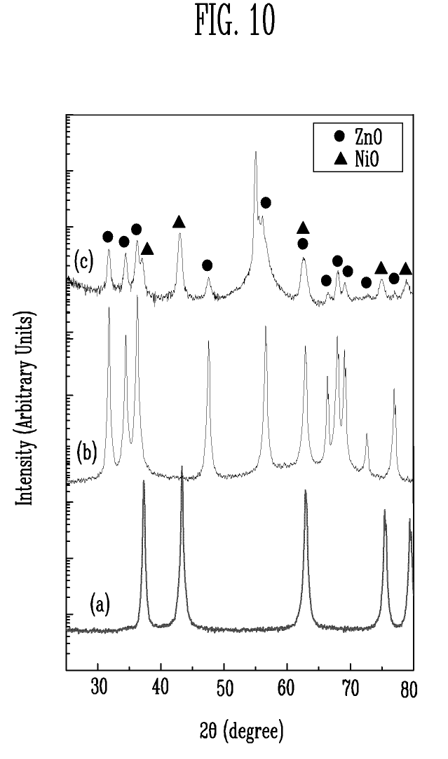

FIG. 10 illustrates a graph of θ-2θ X-ray diffraction patterns of the thin film obtained by annealing at 600° C. in Exemplary embodiment 17. Referring to FIG. 10, (a) is the X-ray diffraction pattern of an NiO oxide ceramic target, (b) is the X-ray diffraction pattern of a ZnO oxide ceramic target, and (c) is the X-ray diffraction pattern of a ZnO—NiO composite-oxide thin film. It can be seen that a crystalline phase of the ZnO thin film is separated from a crystalline phase of the NiO thin film in the ZnO—NiO composite-oxide thin film. Accordingly, it can be seen that a hetero-nano-crystalline composite-oxide thin film is formed.

### Exemplary Embodiment 18

An interdigitated transducer electrode metal was formed to a thickness of 100 nm on a 0.5 mm SiO₂/Si substrate, and then nano-crystalline ZnO—NiO composite-oxide thin films formed by annealing at 400, 450, 500, 550 and 600° C. according to Exemplary embodiments 13 to 17 were formed on the electrode metal, such that a capacitive environmental gas sensor having the structure shown in FIG. 1 was manufactured.

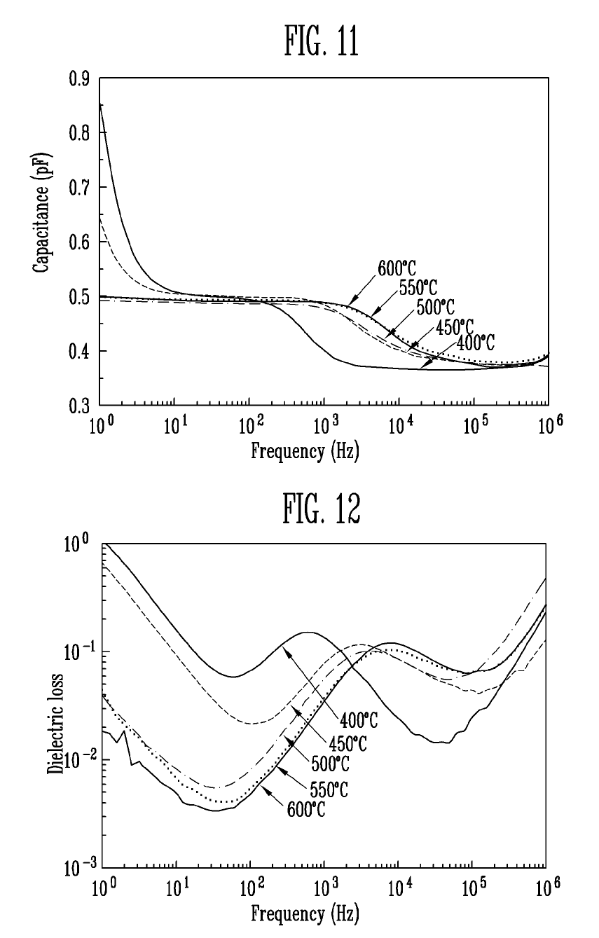

FIGS. 11 and 12 illustrate capacitance and dielectric loss versus frequency of the capacitive environmental gas sensors manufactured by annealing the thin films at various temperatures according to Exemplary embodiments 13 to 17.

Referring to FIGS. 11 and 12, the nano-crystalline ZnO—NiO composite-oxide thin film exhibits decreasing capacitance and a dielectric dispersion phenomenon, i.e., anomalous dielectric loss, at a grain boundary between hetero nano-crystalline particles around a frequency of 1 to 10 kHz.

In a capacitive environmental gas sensor including nano-crystalline composite-oxide according to the present invention, heterogeneous nano-crystalline particles are combined to form grain boundaries at which a potential barrier is formed, thereby forming a high-resistance condenser. This gives the capacitive environmental gas sensor excellent characteristics, such as high sensitivity, high selectivity, long-term stability and low power consumption, and enables it to function as a next-generation ubiquitous sensor system or an environment monitoring system required for more accurate measurement and control of environmentally harmful gases.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A nano-crystalline composite-oxide thin film for an environmental gas sensor, which is formed of hetero-oxide nano-crystalline particles having independent crystalline phases from each other.

2. The thin film according to claim 1, wherein the oxide includes at least two selected from the group consisting of ABO₃-type perovskite oxides (BaTiO₃, metal-doped BaTiO₃, SrTiO₃ and BaSnO₃), ZnO, CuO, NiO, SnO₂, TiO₂, CoO, In₂O₃, WO₃, MgO, CaO, La₂O₃, Nd₂O₃, Y₂O₃, CeO₂, PbO, ZrO₂, Fe₂O₃, Bi₂O₃, V₂O₅, VO₂, Nb₂O₅, Co₃O₄ and Al₂O₃.

3. The thin film according to claim 1, wherein the hetero-oxide nano-crystalline particles have diameters ranging from 1 to 100 nm.

4. An environmental gas sensor, comprising:
a substrate;
a metal electrode formed on the substrate; and
a composite-oxide thin film formed of hetero-oxide nano-crystalline particles on the metal electrode.

5. The sensor according to claim 4, wherein the substrate is one selected from the group consisting of oxide single crystalline and ceramic substrates (MgO, LaA₂O₃ and Al₂O₃), a silicon semiconductor substrate (Si and SiO₂) and a glass substrate.

6. The sensor according to claim 4, wherein the substrate is formed to a thickness of 0.1 to 1 mm

7. The sensor according to claim 4, wherein the metal electrode includes at least one selected from the group consisting of platinum (Pt), gold (Au), silver (Ag), aluminum (Al), nickel (Ni), titanium (Ti), copper (Cu) and chromium (Cr).

8. The sensor according to claim 4, wherein the nano-crystalline composite-oxide thin film is formed of hetero-oxide nano-crystalline particles having independent crystalline phases from each other, and the oxide includes at least two selected from the group consisting of ABO₃-type perovskite oxides (BaTiO₃, metal-doped BaTiO₃, SrTiO₃ and BaSnO₃), ZnO, CuO, NiO, SnO₂, TiO₂, CoO, In₂O₃, WO₃, MgO, CaO, La₂O₃, Nd₂O₃, Y₂O₃, CeO₂, PbO, ZrO₂, Fe₂O₃, Bi₂O₃, V₂O₅, VO₂, Nb₂O₅, Co₃O₄ and Al₂O₃.

9. The sensor according to claim 4, wherein the nano-crystalline composite-oxide thin film is formed to a thickness of 1 to 1000 nm.

10. A method of manufacturing an environmental gas sensor, comprising:
forming a metal electrode on a substrate; and
growing hetero-oxide nano-crystalline particles on the metal electrode and forming a nano-crystalline composite-oxide thin film.

11. The method according to claim 10, wherein the growing of the hetero-oxide nano-crystalline particles is performed by sputtering or pulsed laser deposition using a hetero-oxide ceramic target.

12. The method according to claim 10, wherein the growing of the hetero-oxide nano-crystalline particles is performed by pulsed laser deposition having a dual laser beam using two oxide ceramic targets.

13. The method according to claim 10, wherein the nano-crystalline composite-oxide thin film is deposited at a temperature ranging from room temperature to 800° C.
